(19) United States
(12) Patent Application Publication
(10) Pub. No.: US 2010/0273287 A1
(43) Pub. Date: Oct. 28, 2010

(54) METHODS FOR INTEGRATING QUANTUM WINDOW STRUCTURES INTO SOLAR CELLS

(75) Inventors: Kurt H. Weiner, San Jose, CA (US); Doron Gal, Sunnyvale, CA (US); Gaurav Verma, Sunnyvale, CA (US)

Correspondence Address: Weaver Austin Villeneuve & Sampson LLP, P.O. BOX 70250, OAKLAND, CA, 94612-0250, US

(73) Assignee: REEL SOLAR, INC., San Jose, CA (US)

(21) Appl. No.: 12/764,812

(22) Filed: Apr. 21, 2010

Related U.S. Application Data
(60) Provisional application No. 61/172,083, filed on Apr. 23, 2009.

(51) Int. Cl. H01L 31/18

(52) U.S. Cl. 438/64; 257/E31.117; 257/E31.015

(57) ABSTRACT

The invention relates generally to methods of fabricating photovoltaic stack structures. Methods of the invention find particular use in solar cell fabrication. The performance of a photovoltaic stack can be improved by independent control of fabrication conditions during stack formation, particularly depositing window layers after formation of absorber layers where fabrication conditions of absorber layers would otherwise detrimentally affect quantum grain structures of window layers.

### CROSS-REFERENCE TO RELATED APPLICATIONS

This application claims the benefit of priority under 35 U.S.C. §119(e) to U.S. Provisional application Ser. No. 61/172,083, filed Apr. 23, 2009, which is incorporated by reference herein for all purposes.

### FIELD OF INVENTION

The invention relates generally to methods of fabricating photovoltaic stack structures. Methods of the invention find particular use in solar cell fabrication.

### BACKGROUND

Solar or photovoltaic cells are devices that convert photons into electricity by the photovoltaic effect. Solar cells are assembled together to make solar panels, solar modules, or photovoltaic arrays. The current world-wide solar cell market is based on either crystalline silicon or thin film type solar cell technology.

Thin film solar cells are stacked structures, having layers of materials, including photovoltaic materials, fabricated on a support substrate. As more complex stack structures with varying materials in each layer of the stack are formulated, the fabrication methods used to make the stack become more complex. And since each layer of a photovoltaic stack typically has a unique set of fabrication conditions, each layer's composition and ultimate structure can sometimes directly depend on how subsequent layers of the stack are fabricated. That is, fabrication conditions of a later-formed layer of a stack might well change the characteristics of an earlier-formed layer to the detriment of the earlier-formed layer and the overall performance of the photovoltaic stack.

What is needed, therefore, are improved methods for fabricating photovoltaic stacks. Given the demand for renewable energy, improved methods are particularly important for solar cell fabrication.

### SUMMARY

The invention relates generally to methods of fabricating photovoltaic stack structures. Methods of the invention find particular use in solar cell fabrication. The inventors have found that performance of a photovoltaic stack can be improved by independent control of fabrication conditions during stack formation.

One embodiment is a method of forming a photovoltaic stack, including: (i) depositing an absorber layer on a back contact layer; (ii) performing a process that includes changing the grain structure of the absorber layer so as to optimize the properties of the absorber layer; and (iii) depositing a window layer on the absorber layer. In particular embodiments, the absorber layer includes CdTe and the window layer includes CdS. Processing the absorber layer can include converting the absorber layer to a p-type semiconductor and/or passivating the grain boundaries of the absorber layer. Typically, but not necessarily, the back contact layer is supported by a substrate. This substrate can be planar or a more complex geometry such as a cylinder. Methods of annealing the absorber layer, and deposition of a window layer thereon, are described in more detail below.

Embodiments include forming a window layer on an absorber layer. Embodiments include window layers having a grain size of between about 5 Å and about 300 Å. One embodiment is formation of a CdS window layer via electrodeposition. Forming the window layer after forming and processing the absorber layer is part of one method of managing thermal budget and cutting dependence of window layer characteristics on fabrication parameters of the absorber layer. Other embodiments include depositing a front contact layer over the window layer; and encapsulating the photovoltaic stack so as to form a solar cell module.

Another embodiment is a method of forming a photovoltaic stack, including: (i) depositing a CdTe layer on a back contact layer supported by a substrate; (ii) annealing the CdTe layer; and (iii) electrodepositing a CdS layer on the CdTe layer. This embodiment may further include forming a front contact layer over the CdS layer; and encapsulating the photovoltaic stack so as to form a solar cell module.

Particular aspects of methods of the invention are described below.

### BRIEF DESCRIPTION OF THE DRAWINGS

FIG. 1 depicts a cross-sectional view of a solar cell photovoltaic stack structure.

FIG. 2 depicts a conventional photovoltaic stack formation scenario.

FIG. 3 depicts shows experimental results which illustrate the influence of grain structure on the transmission spectra in a photovoltaic stack.

FIG. 4 depicts a cross-sectional view of a solar cell photovoltaic stack in accord with embodiments of the invention.

FIG. 5 depicts a process flow for a fabrication method in accord with embodiments of the invention.

FIGS. 6A and 6B are graphs showing experimental data comparing transmission of CdS films across a wavelength window between 400 nm and 1100 nm.

### DETAILED DESCRIPTION

### A. Making a Solar Cell

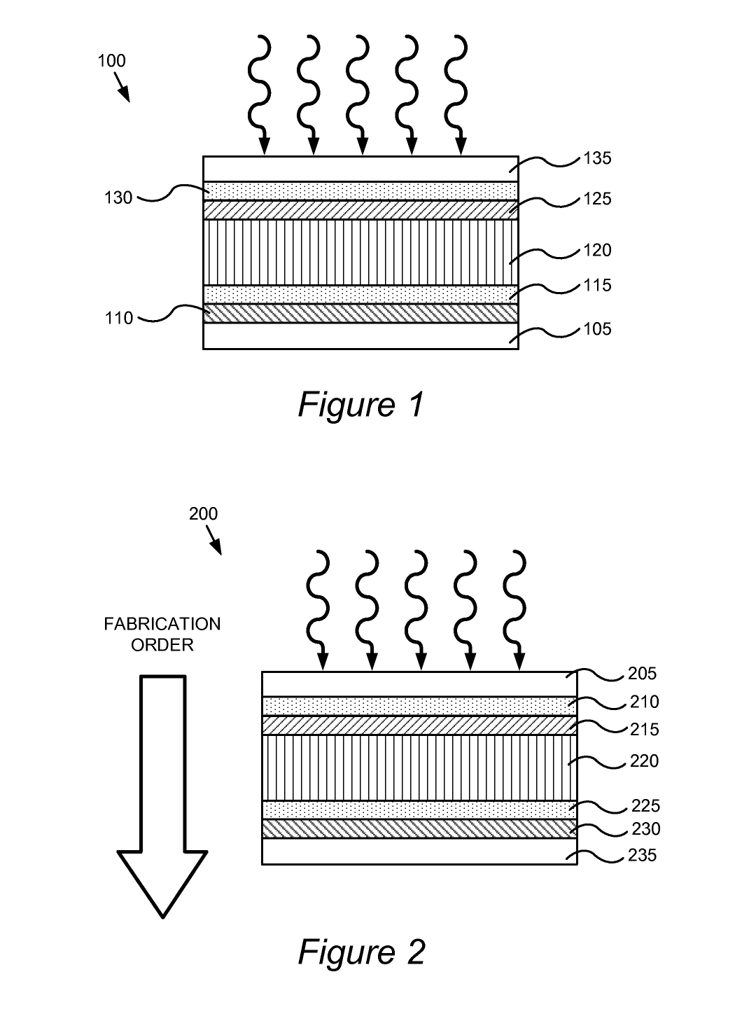

FIG. 1 depicts a simplified diagrammatic cross-sectional view of a typical thin film solar cell, 100. As illustrated, thin film solar cells typically include the following components: back encapsulation, 105, substrate, 110, a back contact layer, 115, an absorber layer, 120, a window layer, 125, a top contact layer, 130, and top encapsulation layer, 135.

Back encapsulation can generally serve to provide encapsulation for the cell and provide mechanical support. Back encapsulation can be made of many different materials that provide sufficient sealing, moisture protection, adequate mechanical support, ease of fabrication, handling and the like. In many thin film solar cell implementations, back encapsulation is formed from glass although other suitable materials may be used. The encapsulation can also take on a variety of different shapes, for example planar glass sheets or cylindrical glass tubes/rods can be used.

A substrate layer can also be used to provide mechanical support for the fabrication of the solar cell. The substrate can also provide electrical connectivity. In many thin film solar cells, the substrate and back encapsulation are the same. Glass plate is commonly used in such instances, although the glass have other geometries, for example, cylindrical glass tubes, rods and/or other glass geometries can be used. Where electrical connectivity is also desired, glass coated with a transparent conductive coating can be used.

A back contact layer can be formed from a thin film of material that provides one of the contacts to the solar cell. Typically, the material for the back contact layer is chosen such that the contact resistance for the electrons/holes flowing from/to the absorber layer is minimized. This result can be achieved by fabricating an ohmic or a tunneling back contact layer. This back contact layer can be formed from many different materials depending of the type of thin film solar cell. For example, in copper indium gallium diselenide (CIGS) solar cells, this layer can be molybdenum. In cadmium telluride (CdTe) thin film solar cells, this back contact layer can be made, for example, of graphite and copper, nickel and/or copper. These materials are merely illustrative examples. That is, the material composition of the back contact layer is dependent on the type of absorber material used in the cell. The thickness of a back contact layer film is typically in the range of a few microns.

The absorber layer is a thin film material that generally absorbs the incident photons (indicated in FIG. 1 by the squiggly arrow lines) and generates electron hole pairs. This absorber material is typically semiconducting and can be a p-type or an n-type semiconductor. An absorber layer can be formed from, for example, CIGS, CdTe or amorphous silicon. The thickness of the absorber layer depends on the semiconducting material, and is typically on the order of microns, varying from a few microns to tens of microns.

A window layer is also typically a thin film of semiconducting material that creates a p-n junction with the absorber layers and, in addition, allows the maximum number of photons in the energy regime of interest to pass through to the absorber layer. The window layer can be an n- or p-type semiconductor, depending on the material used for the absorber layer. For example, the window layer can be formed from a cadmium sulphide (CdS) n-type semiconductor for CdTe and CIGS thin film solar cells. The typical thickness of the layer can vary from 100 Å to 1000 Å.

A top contact is typically a thin film of material that provides one of the contacts to the solar cell. The top contact is made of a material that is transparent to the photons in the energy regime of interest for the solar cell. This top contact layer is typically a transparent conducting oxide (TCO). For CdTe, CIGS, and amorphous silicon thin film solar cells, the top contact can be formed from, for example, indium tin oxide (ITO) or doped, for example with aluminum, zinc oxide (ZnO). The top contact layer thickness can be on the order of a few thousand angstroms.

A top encapsulation layer can be used to provide environmental protection and mechanical support to the cell. The top encapsulation is formed from a material that is highly transparent in the photon energy regime of interest. This top encapsulation layer can be formed from, for example, glass. The glass typically used for the top encapsulation has the same shape as the substrate, for example if a planar substrate is used then the top encapsulation layer is also planar and if the substrate is cylindrical then the top encapsulation layer is also cylindrical.

Thin film solar cells are typically connected in series, in parallel, or both, depending on the needs of the end user, to fabricate a solar module or panel. The solar cells are connected to achieve the desired voltage and current characteristics for the panel. The number of cells connected together to fabricate the panel depends on the open circuit voltage, short circuit current of the cells, and on the desired voltage and current output of the panel. The interconnect scheme can be implemented, for example, by laser scribing for isolation and/or interconnection during the process of the cell fabrication. Once these panels are made, additional components such as bi-pass diodes, rectifiers, connectors, cables, support structures and the like are attached to the panels to install them in the field to generate electricity. Installations can be, for example, in households, large commercial building installations, large utility scale solar electricity generation farms and in space, for example, to power satellites and space craft.

Solar cell photovoltaic stacks are conventionally constructed in an order starting from, for example, a top encapsulation layer, a top contact layer, a window layer, an absorber layer, a back contact layer and so on, that is, in an order opposite of the description of the layers with reference to FIG. 1.

FIG. 2 shows a diagrammatic illustration of conventional photovoltaic stack formation. For illustration purposes, FIG. 2 is described in terms of CdTe-based solar cells. The process starts with the top encapsulation layer, and the cell stack is built by subsequent depositions of top contact layer, window layer, absorber layer, and the like. In this example, the encapsulation layer is substantially planar. The order of fabrication is indicated by the heavy arrow in FIG. 2. Other layers may be formed in addition to the described layers and formation of some of the described layers is optional, depending on the desired cell stack structure.

Referring again to FIG. 2, the TCO-coated glass (for example, the top encapsulation layer 205 and top contact layer 210) can be initially cleaned, dried, cut to size, and edge seamed. Float glass with transparent conductive oxide coatings, for example indium tin oxide, fluorinated tin oxide and doped zinc oxide, are commercially available from a variety of venders, for example, glasses sold under the trademark TEC Glass™ by Pilkington of Toledo, Ohio, and SUNGATE™ 300 and SUNGATE™ 500 by PPG Industries of Pittsburgh, Pa. TEC Glass™ is a glass coated with a fluorinated tin oxide conductive layer. Cylindrical glass is commercially available for example from Schott AG (of Mainz, Germany). A wide variety of solvents, for example deionized water, alcohols, detergents and the like, can be used for cleaning the glass. As well there are many commercially available industrial-scale glass washing apparatus appropriate for cleaning large substrates, for example, Lisec™ (a trade name for a glass washing apparatus and process available from (LISEC Maschinenbau Gmbh of Seitenstetten, Austria).

Once the ITO coated glass is cleaned, a CdS layer, 215, may then be deposited, for example, by using an aqueous solution of, for example, a cadmium salt and elemental sulfur composition. The solution does not have to be aqueous. That is, other solvents, such as dimethylsulfoxide (DMSO), can be used. This deposition can be done using electrodeposition. For electrodeposition, the ITO coated glass can form one of the electrodes. The other electrode can be, for example, made of graphite, and the electrolyte can be, for example, a DMSO solution of a cadmium salt and elemental sulfur. Potential is applied between the electrodes so that CdS is deposited from the solution onto the ITO coated glass substrate. Another method of depositing the CdS layer is chemical deposition, for example via wet chemistry or dry application such as CVD. The CdS deposited is an n-type semiconductor and its thickness is typically between 0.02 μm (200 Å) and 1 μm. Subsequent to the deposition, the window layer can then be annealed, for example under an inert atmosphere such as argon or in air, to achieve film densification and grain growth to improve the electrical, chemical and mechanical properties of the CdS film.

A cadmium telluride layer, 220, can then be deposited by various methods such as dry evaporation, for example, close space sublimation or wet chemical based methods such as electrodeposition on the CdS/TCO/Glass stack (now a substrate for electrodeposition), for example, from an acidic or basic media containing a cadmium salt and tellurium oxide. In this process, the CdS/TCO/Glass substrate forms one of the electrodes and platinum, titanium, graphite etc. or other materials can be used as the other electrode. The electrolyte can contain an acidic or basic media, in solvents such as water, DMSO or other solvents, with a cadmium salt and tellurium oxide, for example. Films of thickness ranging from 1 to 10 μm are typically deposited. Cadmium telluride films may then be annealed at approximately 400° C. in an air or oxygen or CdCl₂ environment so as to improve the electrical properties of the film and also to convert the CdTe film to a p-type semiconductor. It is believed that these methods optimize grain size and thus improve the electrical properties of the films.

After this CdTe deposition and annealing, a laser scribing process is typically performed to remove CdS and CdTe from specific regions (not shown). In this scribing operation, the laser scribing is utilized such that CdS and CdTe are ablated from specific regions of the solar panel. However, the conductive oxide (for example, Al doped ZnO or ITO) is not removed by the laser scribe. Then a second laser scribing step is performed in which CdS, CdTe and TCO are removed from specified regions.

A back contact layer, 225, can then be deposited on the CdTe layer, using for example sputtering or electrodeposition. For example, copper, nickel and/or other metals, alloys and composites can be used for the back contact layer. This back contact fabrication step can be followed by an anneal, for example, at temperatures of between about 150° C. and about 200° C. to form an ohmic contact. The back contact layer can cover the CdTe layer and also fill the vias (not shown) created in the CdTe/CdS layer by the laser scribing process.

After back contact layer deposition and annealing, laser scribing can typically be used to remove back contact layer material from specific areas, but the CdTe layer is not etched away in this process. This removal step can complete the process for isolation and interconnecting the solar cells in series in the solar panel/module.

After the deposition of the back contact layer, an encapsulation layer, 230, can be applied, for example, using ethylvinyl acetate (EVA). Encapsulation protects the photovoltaic stack. Glass, 235, can be added for further structural support (and protection) of the stack.

The above described fabrication process represents a brief outline. Many variants of this process can be employed for the fabrication of CdTe thin film solar cells. For other types of thin film solar cells, different chemicals, and the like can be employed. In this description, example process steps have been described for illustrative purposes. Other steps would typically include additional details of the laser scribing and ablation steps employed for the fabrication of the interconnect schemes and cell isolations, multiple clean and drying steps between the different layer depositions and the like. Values for the layer thicknesses, anneal temperatures, chemical composition and the like described are merely illustrative. These values can vary across a wide range as processes are optimized for many different output variables.

For illustration purposes, electrodeposition of CdS is sometimes described herein as being used in the fabrication of window layers for CdTe-based solar cells. However, window layers can include materials other than CdS, and electrodeposition is not the only method of depositing CdS, that is, the invention is not limited to this exemplary electrodeposition chemistry.

Cadmium sulphide (CdS) is an important semiconductor, and finds particular use as a window layer and n-type semiconductor in, for example, cadmium telluride (CdTe), copper indium gallium diselenide (CIGS), cadmium selenium telluride (CdSeₓTe₁₋ₓ), and the like for solar cell manufacturing. In these exemplary solar cells, CdS can serve two purposes, as an n-type semiconductor for forming the p-n junction with the absorber layer and as a window layer to allow photons to pass through to the absorber layer.

The nanostructure of CdS can be tailored to influence such a window layer's band gap. Band gap has a direct influence on the amount of light the window layer allows to pass through to the absorber layer. For example, a smaller grain size increases the band gap of the semiconductor which allows more light to pass through the window layer.

### B. Integrating Quantum Structures

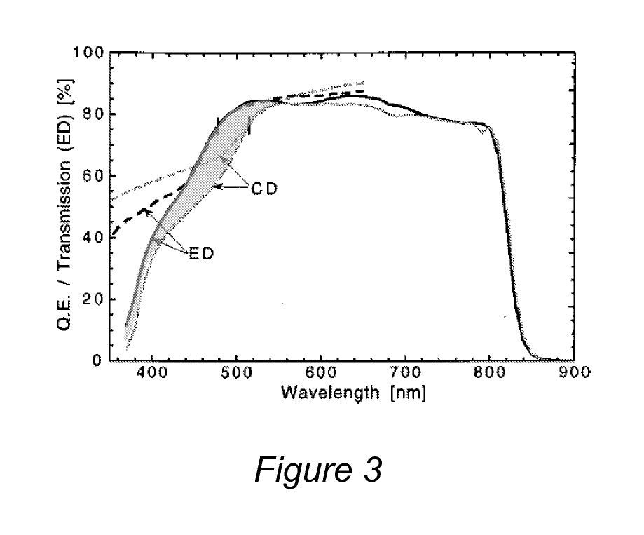

FIG. 3 shows experimental results, which illustrate the influence of grain structure on the transmission spectra of CdS, as published in “Size-quantized CdS Films in Thin Film CuInS₂ Solar Cells” by D. Gal, et. al. Applied Physics Letters 73, 3135, 1998, which is incorporated by reference herein for all purposes. Referring to FIG. 3, creating nano-grain structures of CdS increases the band gap which increases the transmission through the window layer. Data in FIG. 3 show the blue-shift in electro-deposited (ED) versus chemically deposited (CD) CdS window layers due to the smaller grain size of the ED CdS layer, as compared to the CD CdS layer. The blue shift in the transmission spectrum of the ED CdS compared with the nonquantized CD CdS in the 450-540 nm region is denoted with a gray shading. This blue shift due to the smaller grain size in the transmission through the CdS layer increases the photons reaching the absorber layer which increases the efficiency of the solar cell.

The inventors have found that performance of a photovoltaic stack can be improved by independent control of fabrication conditions during stack formation. That is, in the conventional order of fabrication, as outlined above in relation to FIG. 2, the window layer is deposited before formation of the absorber layer. Since conditions for forming the absorber layer can negatively affect the grain size of the window layer, the window layer's performance is inextricably tied to absorber layer formation conditions. By inverting the stack formation order, independent control of fabrication conditions for the absorber layer and window layer is achieved. Embodiments are described in further detail below.

In conventional fabrication methods for solar cells, the window layer is deposited before the deposition of the absorber layer and formation of the back ohmic contact. The absorber layer typically requires processing, such as a relatively high temperature thermal anneal, to improve its photovoltaic properties. For example, a CdTe layer can be annealed in cadmium chloride to passivate its grain boundaries and to convert it to a p-type semiconductor. Anneals can also be utilized to optimize the grain structure of the absorber layer. These anneals can range from about 200° C. to about 650° C. The formation of the ohmic back contact layer also requires an optimization process, such as an anneal, for example at temperatures between about 100° C. and about 300° C. The anneals for improving absorber layer characteristics and for the formation of the back contact negatively impacts the grain structure of the window layer, for example increasing the grain size of the window layer and decreasing the band gap, which decreases the transmission properties of the window layer. In this integration scheme, the properties of the window layer can not be controlled independently and are dependent on the formation and/or optimization conditions for the absorber layer and the back contact. As a result, this scheme typically leads to degradation of the properties of the window layer and a lower performance solar cell. By decoupling the formation parameters of the window layer from those of the absorber layer, each layer is independently optimized for improved function of each layer and also the final solar cell. Embodiments of the present invention provide methods of fabrication of solar cells that permit independent control of the properties of the window and absorber layer.

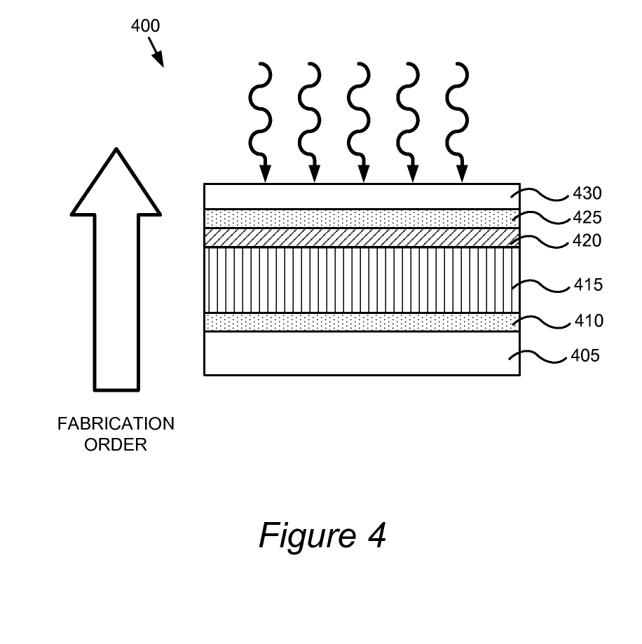

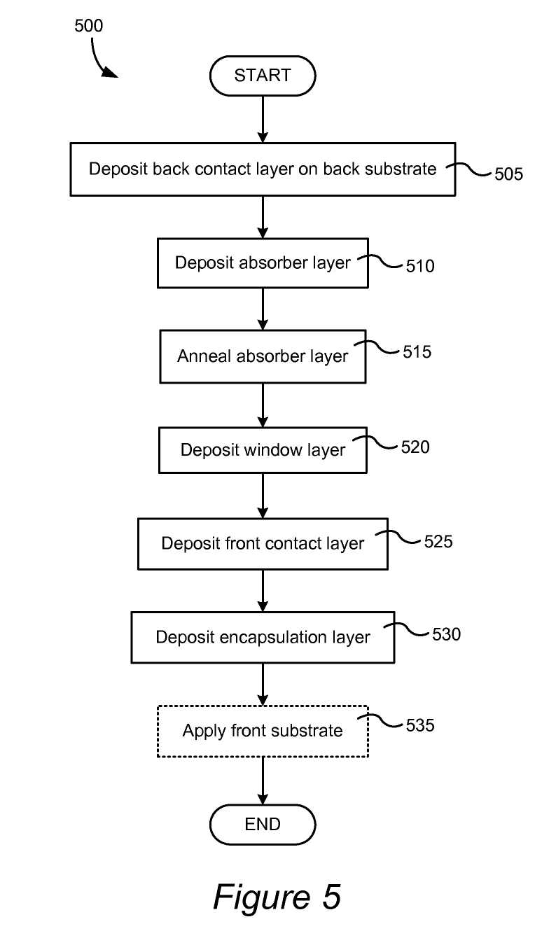

As mentioned above, one embodiment is a method of forming a photovoltaic stack, including: (i) depositing an absorber layer on a back contact layer; (ii) performing a process that includes changing the grain structure of the absorber layer so as to optimize the properties of the absorber layer; and (iii) depositing a window layer on the absorber layer. For convenience, embodiments are described below in relation to FIGS. 4 and 5 which relate to devices and methods in a larger context.

FIG. 4 illustrates a cross-section, 400, of a photovoltaic stack fabricated according to a process flow, 500, as depicted in FIG. 5. Various embodiments include more or less process parameters and/or stack layers. This more detailed description is provided for a more thorough understanding of the context of embodiments of the invention.

Referring to FIG. 4, photovoltaic stack 400 is a thin film stack including the following components: substrate, 405, a back contact layer, 410, an absorber layer, 415, a window layer, 420, a top contact layer, 425, and top encapsulation layer, 430. As described above, photovoltaic stacks can also have a back encapsulation layer, which in this example would be adjacent to substrate 405, at the bottom (as depicted) of the stack. Back encapsulation can provide additional mechanical support and/or protection of the stack from outside contamination, for example, from moisture. In some embodiments, glass serves both as the back substrate and back encapsulation layer.

Referring also to FIG. 5, back contact layer, 410 is applied to back substrate layer 405, see 505. The back substrate layer can be planar or a more complex geometry such as a cylinder or a rod. Back contact layer 410 is a thin film of material that provides one of the contacts to the solar cell. In one embodiment, the back contact layer includes at least one of molybdenum, nickel, graphite, copper, tin and aluminum. The contact can also be fabricated through multiple layers for example using copper, graphite and a metal layer such as aluminum, tin etc. on top. This multiple layer contact scheme allows optimization of contact and series resistance. In one embodiment, the thickness of the back contact layer is between about 0.1 micron and about 10,000 microns, in another embodiment between about 0.1 microns and about 10 microns, in another embodiment between about 0.1 microns and about 1 micron.

Next, an absorber layer film, 415, is deposited, see 510. An absorber layer can be formed from, for example, CIGS, CdTe or amorphous silicon. In one embodiment, the absorber layer includes CdTe and/or is CdTe. In the embodiment described above, a process is performed that includes changing the grain structure of the absorber layer so as to optimize the properties of the absorber layer. Although the process for optimizing absorber layers may be described in terms of annealing, other processes that affect the grain structure of the absorber layer can alternatively be performed so as to optimize the absorber layer. In one embodiment, this includes annealing the absorber layer, see 515.

When the absorber layer is CdTe, annealing the CdTe layer includes heating at between about 250° C. and about 600° C. for between about 1 minute and about 60 minutes, in another embodiment between about 250° C. and about 450° C. for between about 1 minutes and about 30 minutes, in another embodiment between about 350° C. and about 450° C. for between about 10 minutes and about 20 minutes. In one embodiment, annealing the CdTe layer includes heating in the presence of cadmium chloride. The CdCl₂ can be dissolved in a solvent, for example an alcohol such as methanol, and spray applied to the surface of the CdTe. Annealing can be done under inert atmosphere or in air.

The processing of the absorber layer may also include converting the absorber layer to a p-type semiconductor and/or passivating the grain boundaries of the absorber layer and/or improving or establishing ohmic contact with the back contact layer. The thickness of the CdTe absorber layer depends on the semiconducting material, and is typically on the order of microns, varying from a few microns to tens of microns. In one embodiment, the thickness of the absorber layer is between about 0.5 micron and about 15 microns, in another embodiment between about 0.5 micron and about 5 microns, in another embodiment between about 0.5 microns and about 2 microns.

After processing the absorber layer for optimal properties, a window layer, 420, is deposited, see 520. The window layer is formed after deposition of the absorber layer and after performing the process for optimizing such absorber layer (that affects the grain structure and electrical properties of the absorber layer), because such optimization processes can adversely affect the nanostructure of the window layer if performed while the window layer is part of the stack. If the window layer is formed after optimization of the absorber layer, this issue is avoided. Window layer 420 is a film of semiconducting material that creates a p-n junction with absorber layer 415 and allows the maximum number of photons in the energy regime of interest to pass through to absorber layer 415. It is desirable to maintain nanostructures in the window layer for the reasons described herein. In one embodiment, the window layer includes at least one of CdS, ZnSe (zinc selenide), ZnS (zinc sulphide), ZnO (zinc oxide), Cd(OH)SH (cadmium hydroxide sulphide), In(OH)SH (indium hydroxide sulphide), SnO₂ (tin (II) oxide) and Sn(O₂)S₂ (tin (IV) oxide sulphide). Window layer 420 can be an n- or p-type semiconductor, depending on the material used for the absorber layer. In one embodiment, the window layer is formed from a cadmium sulphide (CdS) which is an n-type semiconductor used. Cadmium sulfide films are used, for example, in CdTe and CIGS thin film solar cells. In one embodiment, the thickness of the window layer is between about 50 Å and about 2000 Å, in another embodiment between about 50 Å and about 1000 Å, in another embodiment between about 50 Å and about 500 Å.

Nanostructured CdS films can be produced, for example, via electrodeposition as described herein (for example as described in relation to FIG. 3 and/or in the examples below), wet chemical deposition, dry sputtering and the like. Nanostructured grain sizes make the grains behave as quantum structures. The quantum nature of the grains in the film increases the window layer's band gap, allowing a greater percentage of the incident radiation to pass through to the absorber layer, thereby increasing the efficiency of the solar cell. The thermal budget to which the window layer is subjected is carefully controlled so as to maintain the quantum nature of the grains and to take advantage of the increase in the band gap. In one embodiment, the window layer material includes a grain size of between about 5 Å and about 300 Å, in another embodiment between about 5 Å and about 50 Å, in another embodiment between about 5 Å and about 10 Å.

Referring again to FIGS. 4 and 5, after the window layer is formed, a front contact layer, 425, is formed, see 525. Front (or top) contact layer 425 is a thin film of material that provides the other contact for photovoltaic stack 400. As described above, the top contact is made of a material that is transparent to the photons in the energy regime of interest for the ultimate solar cell. In one embodiment, the top contact layer includes at least one of indium tin oxide (ITO), aluminum doped zinc oxide, zinc oxide, fluorinated tin oxide, and/or a grid of metallic lines or a combination of transparent conductive oxide and a grid of metallic lines. The top contact layer thickness can be on the order of thousands of angstroms. In one embodiment, the thickness of the top contact layer is between about 500 Å and about 10,000 Å, in another embodiment between about 500 Å and about 5000 Å, in another embodiment between about 500 Å and about 3000 Å.

After the front contact layer is formed, an encapsulation layer, 430, is deposited, see 530. Encapsulation is used to provide environmental protection and/or further mechanical support to the cell. The top encapsulation is formed from a material that is highly transparent in the photon energy regime of interest. This top encapsulation layer can be formed from, for example, glass or other transparent material such as a polymeric material. In the event the encapsulation layer is not mechanically strong enough to provide support, a front substrate may optionally be applied, see 535. In one embodiment, the front contact and top encapsulation layers are applied in one step, for example, using a glass (the encapsulation layer and supportive substrate) coated with a TCO (the front contact), where the TCO adjoins the window layer. In this embodiment, heating or other processing may be needed to ensure proper bonding and ohmic contact between the TCO and the window layer. In another embodiment, glass alone serves as an encapsulation layer (and front substrate for mechanical support) that is applied over the front contact. After the encapsulation layer is applied, the process flow ends.

In one embodiment, the absorber layer is CdTe and the window layer is CdS. Another embodiment is a method of forming a photovoltaic stack, including: (i) depositing a CdTe layer on a back contact layer supported by a substrate; (ii) annealing the CdTe layer; and (iii) electrodepositing a CdS layer on the CdTe layer. In one embodiment, the window layer includes a grain size of between about 5 Å and about 300 Å, in another embodiment the window layer includes a grain size of between about 10 Å and about 200 Å, and in another embodiment the window layer includes a grain size of between about 20 Å and about 100 Å. In one embodiment, the method further includes: (iv) forming a front contact layer over the CdS layer; and (v) encapsulating the photovoltaic stack so as to form a solar cell module.

### EXAMPLES

Cadmium sulfide films were formed via electrodeposition and conventional chemical deposition and their transmission spectra compared to show: 1) that electrodeposited CdS films show superior transmission properties for use in photovoltaic stacks, and 2) that annealing at temperatures typical for annealing CdTe absorber layers can have detrimental effects on the optical properties of the electrodeposited CdS films.

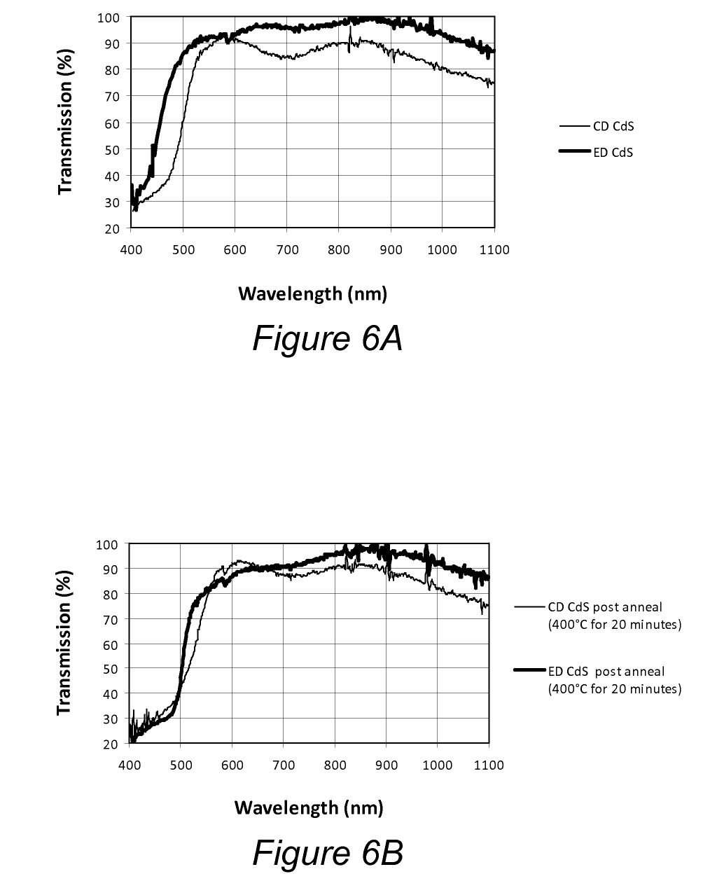

Cadmium sulfide films were electrodeposited galvanostatically from a DMSO solution of cadmium chloride and sulfur (each 0.05M) onto TEC 15 glass coated with fluorine doped tin oxide. In the transmission spectrums shown in FIG. 6 the data was normalized to remove the effect of the glass and isolate only the transmission through the CdS layer. The electrodepositions were carried out at 120° C., for 32 seconds using agitation and a current density of 2 mA/cm². Under these conditions, a 32 second deposition corresponded to a film approximately 100 nm thick, based on a measured resistivity of approximately 64.4 mΩ/cm².

Chemical deposition of CdS was done in an aqueous solution consisting of CdO, aqueous ammonia solution, diaminoethane, sodium hydroxide and thiourea in de-ionized water. The deposition was carried out at 75° C. using agitation. Deposition for approximately 25 minutes resulted in a 100 nm thick CdS film.

The electrodeposited and chemically deposited films were compared according to their transmission spectra over a wavelength span of 400 nm to 1100 nm. FIGS. 6A and 6B are graphs showing experimental data comparing transmission of electrodeposited CdS films across this wavelength window.

Referring to FIG. 6A, the electrodeposited film exhibited a greater transmission than the chemically deposited film across substantially the entire wavelength window. Each film was subjected to an anneal at 400° C. for 20 minutes and their transmission properties again compared, see FIG. 6B. The data shows that such relatively high annealing temperatures, for example as would be used to process an absorber layer, are detrimental to the transmission properties of the electrodeposited CdS layer over a wide portion of the wavelength window. Even so, the electrodeposited CdS film showed superior transmission properties than the chemically deposited CdS film.

Although the foregoing invention has been described in some detail for purposes of clarity of understanding, it will be apparent that certain changes and modifications may be practiced within the scope of the appended claims. Therefore, the present embodiments are to be considered as illustrative and not restrictive and the invention is not to be limited to the details given herein, but may be modified within the scope and equivalents of the appended claims.

What is claimed is:

1. A method of forming a photovoltaic stack, comprising:
(i) depositing an absorber layer on a back contact layer;
(ii) performing a process that comprises changing the grain structure of the absorber layer so as to optimize the properties of the absorber layer; and
(iii) depositing a window layer on the absorber layer.

2. The method of claim 1, wherein the window layer comprises at least one of CdS, ZnSe, ZnS, ZnO, Cd(OH)SH, In(OH)SH, SnO₂ and Sn(O₂)S₂.

3. The method of claim 2, wherein the absorber layer comprises CdTe and the window layer comprises CdS.

4. The method of claim 3, wherein the process further comprises converting the absorber layer to a p-type semiconductor.

5. The method of claim 4, wherein the process further comprises passivating the grain boundaries of the absorber layer.

6. The method of claim 5, wherein the process further comprises annealing the absorber layer.

7. The method of claim 6, wherein the window layer comprises a grain size of between about 5 Å and about 300 Å.

8. The method of claim 7, wherein depositing the window layer comprises an electrodeposition.

9. The method of claim 8, wherein the electrodeposition comprises electrodepositing from a solution of cadmium chloride and sulfur in DMSO.

10. The method of claim 8, further comprising:
(iv) depositing a front contact layer over the window layer; and
(v) encapsulating the photovoltaic stack so as to form a solar cell module;
wherein the back contact layer is supported by a substrate.

11. The method of claim 10, wherein the substrate and the back contact layer each have a planar or a cylindrical geometry.

12. A method of forming a photovoltaic stack, comprising:
(i) depositing a CdTe layer on a back contact layer supported by a substrate;
(ii) annealing the CdTe layer; and
(iii) electrodepositing a CdS layer on the CdTe layer.

13. The method of claim 12, wherein annealing the CdTe layer comprises heating at between about 250° C. and about 600° C. for between about 1 minute and about 60 minutes.

14. The method of claim 13, wherein annealing the CdTe layer comprises heating in the presence of cadmium chloride.

15. The method of claim 12, wherein the window layer comprises a grain size of between about 5 Å and about 300 Å.

16. The method of claim 15, wherein electrodepositing the CdS layer on the CdTe layer comprises electrodepositing from a solution of cadmium chloride and sulfur in DMSO.

17. The method of claim 16, further comprising:
(iv) forming a front contact layer over the CdS layer; and
(v) encapsulating the photovoltaic stack so as to form a solar cell module.

18. The method of claim 17, wherein the substrate and the back contact layer each have a planar or a cylindrical geometry.
